(19) United States
(12) Patent Application Publication
(10) Pub. No.: US 2025/0076355 A1
(43) Pub. Date: Mar. 6, 2025

(54) CONTACT RESISTANCE MEASUREMENT METHOD

(71) Applicant: Infineon Technologies AG, Neubiberg (DE)

(72) Inventors: Ralf Arnold, Poing (DE); Kevin Stoddart, Kirkcaldy (GB)

(21) Appl. No.: 18/460,208

(22) Filed: Sep. 1, 2023

(51) Int. Cl. G01R 27/20

(52) U.S. Cl. CPC G01R 27/205; G01R 31/2607

(57) ABSTRACT

A method for determining a contact resistance may include performing voltage and current measurements associated with a pin of a device under test (DUT) using a parameter measurement circuit, obtaining at least three voltage-current measurement pairs. An emission coefficient may be determined from the voltage-current measurement pairs. A contact resistance may be calculated from the emission coefficient and the voltage-current measurement pairs and stored.

The present disclosure relates to the field of semiconductor device testing, and in particular, to a method for determining an emission coefficient associated with a semiconductor device.

### BACKGROUND

To ensure the function and evaluate the performance of semiconductor devices, testing is an important step for the semiconductor devices. The tests need to obtain a high level of accuracy while finishing in a short amount of time to keep the production test costs low. In order to perform accurate testing on a device, accurate knowledge of various parameters associated with the device, for example, an emission coefficient of a diode associated therewith, is required. Further, during testing, some unknown variables may be introduced by the test equipment, for example, contact resistance which greatly affects the accuracy of testing. Therefore, in order to get accurate results in testing and validation of devices, it is important to have an accurate knowledge of the emission coefficient of the device (or a diode associated therewith) and/or the contact resistance, before the testing is performed on the device.

In a prior patent U.S. Pat. No. 11,555,844 a repetitive/iterative process is proposed for measuring the emission coefficient.

### BRIEF DESCRIPTION OF THE DRAWINGS

Some examples of circuits, apparatuses and/or methods will be described in the following by way of example only. In this context, reference will be made to the accompanying Figures.

FIG. 1 depicts a simplified block diagram of a test system, according to one embodiment of the disclosure.

FIG. 2 depicts a simplified diagram of a DUT having an ESD protection structure associated therewith, according to one embodiment of the disclosure.

FIG. 3 illustrates a flowchart of an emission coefficient determination method that is utilized to determine an emission coefficient associated with a DUT terminal, according to one embodiment of the disclosure.

FIG. 4 illustrates an example implementation of a test system, according to one embodiment of the disclosure.

FIG. 5 illustrates one possible simplified test setup configured to measure a contact resistance associated with a DUT terminal, according to one embodiment of the disclosure.

### DETAILED DESCRIPTION

In one embodiment of the disclosure, a method for determining an emission coefficient is disclosed.

The present disclosure will now be described with reference to the attached drawing figures, wherein like reference numerals are used to refer to like elements throughout, and wherein the illustrated structures and devices are not necessarily drawn to scale. As utilized herein, terms “component,” “system,” “interface,” “circuit” and the like are intended to refer to a computer-related entity, hardware, software (e.g., in execution), and/or firmware. For example, a component can be a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server can also be a component. One or more components can reside within a process, and a component can be localized on one computer and/or distributed between two or more computers. A set of elements or a set of other components can be described herein, in which the term “set” can be interpreted as “one or more.”

Further, these components can execute from various computer readable storage media having various data structures stored thereon such as with a module, for example. The components can communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from conte8 to be directed to a singular form. Furthermore, to the event that the terms “including”, “includes”, “having”, “has”, “with”, or variants thereof are used in either the detailed description and the claims, such terms are intended to be inclusive in a manner similar to the term “comprising.”

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

As indicated above, testing is an important step for semiconductor devices to ensure the function of devices and evaluate the performance of the devices. Further, as indicated above, it is important to have an accurate knowledge of the emission coefficients of the device (or a Diode Element associated therewith) and/or the contact resistance, before the testing is performed on the device inputs/outputs. The device that is being tested is sometimes referred to herein as a device under test (DUT). The emission coefficient n (eta) is a variable to account for imperfections in the junctions within a diode element. It expresses the deviation of the diode curve from the ideal Shockley model (with η=1). In some embodiments, the emission coefficient of an input/output pin of a DUT comprises an emission coefficient associated with a diode element coupled to the input/output pin of the DUT. In some embodiments, the diode element may include an electrostatic discharge (ESD) diode and/or a parallel circuit of multiple diodes and/or parasitic diodes e.g. from a driver transistor. In current implementations, during testing or validation, the value of the emission coefficient for a normal diode is usually estimated to be between 1 and 2.

However, the emission coefficient associated with an input/output pin of a DUT could differ depending on the input/output (I/O) structure of the pin. For example, in some embodiments, an ESD structure of the input/output pin and a driver structure (e.g. the parasitic bulk diode) associated with the input/output pin together forms a combined diode element with different emission coefficient. Therefore, in order to get accurate values of the emission coefficients of a device or a DUT, a method and an apparatus to determine the emission coefficient of a diode element associated with the device is proposed in this disclosure. In some embodiments, the proposed emission coefficient determination method enables one to determine accurate values of the emission coefficients for the various pins of the DUT terminals, thereby facilitating an accurate simulation model derivation of the DUT. In some embodiments, the determination of accurate values of the emission coefficients of a DUT is also essential for the determination of accurate contact resistances of the DUT terminals. In the embodiments described throughout the disclosure, the terms emission coefficient and eta are used interchangeably and are construed to have the same meaning.

In some embodiments, the term contact resistance refers to a contribution to the total resistance of a system which can be attributed to the contacting interfaces of electrical leads and connections (e.g., a physical connection between a test system and the DUT) as opposed to the intrinsic resistance. In current implementations, testing and validation of the DUT is done based on an estimated value for the contact resistance. For example, in some embodiments, the contact resistance is estimated based on getting a feedback about the resistance of the contactors associated with the test equipment. Further, in some embodiments, the contact resistance contributed by a test equipment is measured on a device once, and the same contact resistance value is used for multiple productions boards of the device. However, the contact resistance contributed by a test equipment is variable over temperature and also dependent on the usage/worn-out factor of the test equipment contactors (e.g., pogo contacts, probe needles, sockets etc.). Therefore, utilizing an estimated contact resistance for testing leads to inaccurate results, which further leads to yield loss because potentially functional devices are failing the validation due to the large error range.

In order to overcome the above disadvantages, a method and an apparatus to determine a contact resistance contributed by a test equipment based on measurements on a DUT is proposed in this disclosure. The key idea that is utilized herein is to determine the contact resistance based on measurements across a diode element associated with an input pin of the DUT. As indicated above, the diode element may include an electrostatic discharge (ESD) diode or a parallel circuit of multiple diodes or parasitic diodes e.g. from a driver transistor. In some embodiments, the proposed method to measure the contact resistance requires information on the emission coefficient of the diode element. In some embodiments, the proposed contact resistance determination method is based on taking measurements associated with the input pin of the DUT. In some embodiments, the proposed method enables to calculate an accurate value for the contact resistance at the input pin of the DUT before every validation.

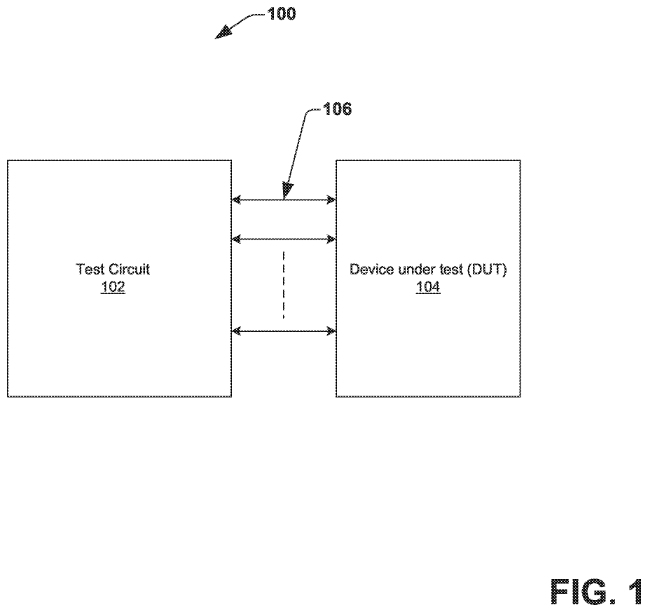

FIG. 1 depicts a simplified block diagram of a test system 100, according to one embodiment of the disclosure. The test system 100 comprises a test circuit 102 and a device under test (DUT) 104. In some embodiments, the test circuit 102 is configured to perform measurements on the DUT 104, in order to evaluate the function and performance of the DUT 104. In some embodiments, the DUT 104 comprises a device that is being tested. In some embodiments, the DUT 104 comprises an integrated circuit (IC) comprising a plurality of pins, for example, control pins, I/O pins, interface pins etc. In the embodiments described herein, the various pins associated with the DUT 104 that are to be measured are referred to as an input pin for the ease of reference and is not to be construed as limiting. In other embodiments, however, the DUT 104 can include, other devices, for example, discrete components like diodes etc. In some embodiments, the test circuit 102 is configured to couple to an input pin associated with the DUT 104 via a test connection 106. In a case when the DUT 104 comprises a discrete component, the term “input pin” may refer to an input port (or lead) of the component. In some embodiments, a test connection 106 connects an input pin of the DUT 104 to a test channel of the test circuit 102. In some embodiments, the test circuit 102 may be configured to perform measurements associated with one or more input pins of the DUT 104 in parallel. In such embodiments, the test circuit 102 may comprise a plurality of test connections 106 in order to couple the various pins of the DUT 104 with one test channel each of the test circuit 102.

In some embodiments, the test circuit 102 is configured to perform measurements associated with an input pin of the DUT 104 via a respective test connection 106 associated therewith. In some embodiments, the test circuit 102 comprises measuring instruments associated with each test channel, in order to perform measurements associated with a respective test connection 106 or a respective input pin of the DUT 104. In some embodiments, the test circuit 102 further comprises one or more processors (e.g., microcontrollers) configured to process the measured parameters and evaluate the performance of the input pins. In some embodiments, the test connections 106 comprise contactors by which the DUT pins are contacted, for example, test sockets for inserting the DUTs, pogo contacts, probe needles etc. In some embodiments, the test circuit 102 is configured to determine an emission coefficient associated with an input pin of the DUT 104 (or with respect to one or more pins of the DUT 104, when the DUT 104 comprises a plurality of input pins). In some embodiments, the emission coefficient n is a variable to account for imperfections in the junctions within a diode element.

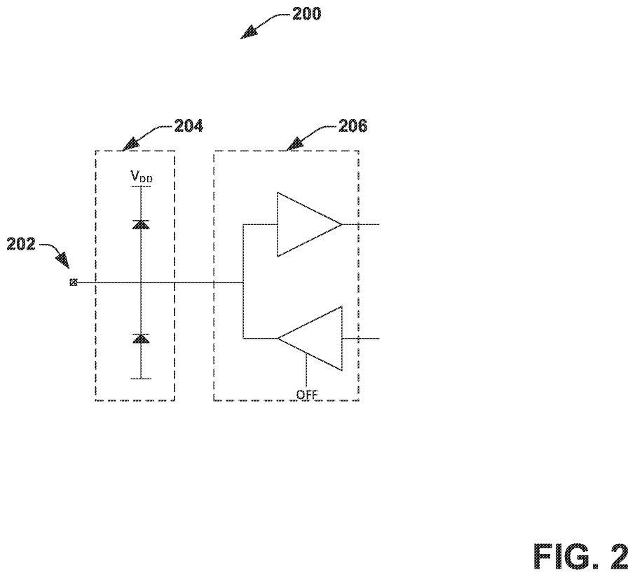

In some embodiments, determining the emission coefficient of the DUT 104 comprises determining the emission coefficient of a diode element associated with the DUT 104. In some embodiments, DUT 104 may comprise a diode element associated with one or more input pins of the DUT 104. The diode element may include an electrostatic discharge (ESD) diode, as illustrated in FIG. 2. However, in other embodiments, the diode element may comprise a parallel circuit of multiple diodes, parasitic diodes, for example, from a driver transistor etc. Referring to FIG. 2, FIG. 2 depicts a simplified diagram of a DUT 200 having an ESD protection structure 204 associated therewith. The DUT 200 further comprises a contact pad 202 associated with an input pin and an input/output buffer circuit 206. In some embodiments, the DUT 200 can be included within the DUT 104 in FIG. 1. In some embodiments, the test circuit 102 may be configured to determine the emission coefficient associated with an input pin of the DUT 104 based on one or more measurements associated with the input pin (e.g., the contact pad 202 in FIG. 2). In some embodiments, the test circuit 102 may be configured to determine the emission coefficient associated with an input pin of the DUT, in accordance with a predefined emission coefficient determination method, further details of which are given in embodiments below.

In some embodiments, during testing, the test connections 106 of the test circuit 102 contribute a contact resistance. In some embodiments, other parasitic resistances between the test circuit 102 and the DUT 104 also contribute to the contact resistance. Therefore, in some embodiments, the test circuit 102 is further configured to determine a contact resistance at an input pin of the DUT 104 based on measurements (e.g., voltage and current measurements) across the diode element associated with an input pin of the DUT 104, further details of which are given in embodiments below. In some embodiments, the test circuit 102 is configured to perform measurements associated with the DUT 104 (or an input pin associated therewith) based on coupling to a contact pad (e.g., the contact pad 202 in FIG. 2) associated with an input pin of the DUT 104. In some embodiments, a voltage measured across the diode element (e.g., at the contact pad 202 in FIG. 2) includes a voltage drop across the diode element and a voltage drop due to the contact resistance. In some embodiments, the test circuit 102 may be configured to perform voltage and current measurements based on forcing current to the input pin of the DUT 104 and measuring a corresponding voltage at the input pin of the DUT 104. However, in other embodiments, the test circuit 102 may be configured to perform voltage and current measurements based on forcing voltage to the input pin of the DUT 104 and measuring a corresponding current at the input pin of the DUT 104.

Some relevant mathematics will now be presented.

Three currents may be forced through the input pin of the device under test, I_{low}, I_{mid} and I_{high} for example −5 mA, −10 mA and −20 mA. Those skilled in the art will appreciate that many alternative current values may be selected. By selecting values that double, i.e. −10 mA is double −5 mA and −20 mA is double −10 mA, that is in the ratio 1:2:4.

The respective voltages V_{low}, V_{mid}, V_{high} corresponding to the low medium and high currents, I_{low}, I_{mid} and I_{high} are then measured.

These values allow two different contact resistance values CRES1 and CRES2 to be calculated, as a function of the emission coefficient η.

$$CRES 1 = \frac{( Vhigh - Vlow ) - ( η . V T . ln ( \frac{Ihigh}{Ilow} ) )}{Ihigh - Ilow} CRES 2 = \frac{( Vhigh - Vlow ) - ( η . V T . ln ( \frac{Ihigh}{Imid} ) )}{Ihigh - Imid} \qquad ( 1 )$$

However, as η is not known, these equations do not allow calculation of the emission coefficient η or the actual contact resistance.

In a prior approach, different values of n were tried, for example all values of η from 1 to 6 with a resolution of 0.01, i.e. 500 different values of η. The value of η giving the closest two contact resistance values is then determined as the estimate of the value of η and the contact resistance value corresponding to this value of η taken as the contact resistance value.

However, such an approach is computationally intensive.

The inventors have realized that a better approach exists.

In principle, the two different contact resistance values should reflect the same actual contact resistance, i.e. CRES1=CRES2 when η is correctly selected.

If one takes CRES1=CRES2 in equations 1, and also takes the known values of the currents, I_{high}=2I_{mid} and I_{mid}=2I_{low} then it is possible to rearrange the resulting equation to give

$$η = \frac{ABS ( 2 * ( Vhigh - Vlow ) ) - ABS ( 3 * ( Vhigh - Vmid ) )}{V T * ln ( 2 )} \qquad ( 2 )$$

Those skilled in the art will realize that a similar equation can be calculated in the case that the currents are not in the 1:2:4 ratio taken here, as long as the ratio of currents is known. The numerical coefficients in the equation will however be different.

Thus, in some embodiments other current values are selected and the respective voltages measured. In some embodiments voltage values are selected and the respective currents measured.

In some embodiments the value of n may be given by solving equation (3) for η:

$$\frac{( Vhigh - Vlow ) - ( η . V T . ln ( \frac{Ihigh}{Ilow} ) )}{Ihigh - Ilow} = \frac{( Vhigh - Vlow ) - ( η . V T . ln ( \frac{Ihigh}{Imid} ) )}{Ihigh - Imid} \qquad ( 3 )$$

Note that since voltages V_{low}, V_{mid}, V_{high} I_{low}, I_{mid} and I_{high} are known, this is relatively straightforward. Those skilled in the art will realize that the equation can be rearranged and presented differently.

The determined value of η can then be substituted into equation (1) which then gives two alternative values CRES1 and CRES2 which both represent the contact resistance. The value should be the same since equation (2) has been calculated on this basis.

This approach provides a good estimate of the contact resistance without the need for iteration or complex processing.

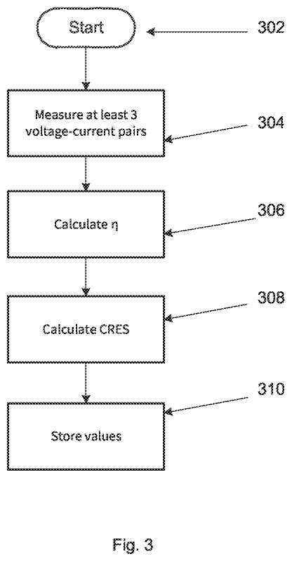

FIG. 3 illustrates a flow chart of an example of a method 300 according to one embodiment of the disclosure. In a first step 304, voltage and current measurements associated with an input pin of a device under test (DUT) using a parameter measurement circuit are obtained for at least three voltage-current measurement pairs. Then, in step 306, the emission coefficient η from the voltage current measurement pairs is calculated as set out above. Next, in step 308, the contact resistance is calculated from the emission coefficient and the voltage-current measurement pairs. In step 310 the determined contact resistance and emission coefficients are stored in a memory circuit for subsequent access in testing or validating the DUT.

In some embodiments of the invention a known current is forced through the pin and the voltage measured. In some embodiments of the invention a fixed voltage is applied and the current measured.

FIG. 3 illustrates a flow chart of an emission coefficient determination method 300 that is utilized to determine an emission coefficient associated with a DUT, according to one embodiment of the disclosure. In some embodiments, the emission coefficient determination method 300 may be implemented within the test circuit 102 in FIG. 1, in order to determine the emission coefficient associated with an input pin of the DUT 104. Therefore, the emission coefficient determination method 300 is explained herein with reference to the test circuit 102 in FIG. 1. However, in other embodiments, the emission coefficient determination method 300 may be implemented in any other test circuits and is not to be construed to be limiting.

At 302, an instruction to determine an emission coefficient associated with an input pin of the DUT 104 is received at the test circuit 102. At 304, a plurality of current and voltage measurements (e.g., N) associated with the input pin of the DUT 104 is performed at the test circuit 102.

At 306, the emission coefficient η is calculated. In the case where the current values used are in the ratio 1:2:4 then equation (2) can be used directly. In other cases, a similar equation can be calculated but the coefficients will be different.

Then, at 308 one or two or more contact resistance values (Cres) associated with the input pin of the DUT 104 is calculated at the test circuit 102, respectively based on the plurality of current and voltage measurements (measured at 304). In some embodiments, this may be done using equation (1) above.

Then, at 310 the contact resistance value and emission coefficients are stored.

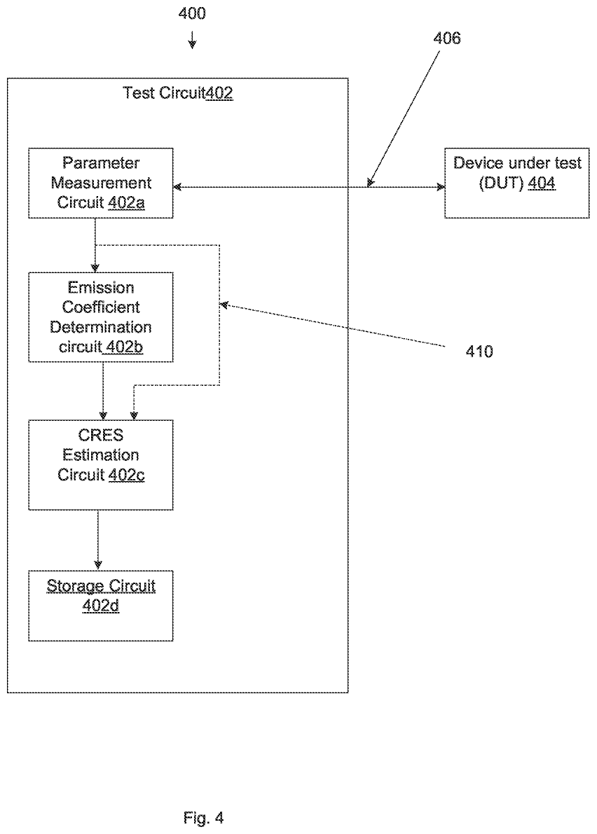

FIG. 4 illustrates an example implementation of a test system 400, according to one embodiment of the disclosure. In some embodiments, the test system 400 depicts one possible way of implementation of the test system 100 in FIG. 1. The test system 400 comprises a test circuit 402 and a device under test (DUT) 404. In some embodiments, the test circuit 402 is configured to perform measurements on the DUT 404, in order to evaluate the function and performance of the DUT 404. In some embodiments, the test circuit 402 is configured to perform measurements on the DUT 404 based on utilizing a test connection 406 that connects the DUT 404 to a test channel of the test circuit 402. In this embodiment, the test circuit 402 is shown to include only one test connection 406 couple to the DUT 404 (or an input pin associated therewith). However, in other embodiments, the test circuit 402 may include more than one test connection configured to couple to one or more input pins of the DUT 404. In some embodiments, the test circuit 402 comprises a parameter measurement circuit 402a, a contact resistance estimation circuit 402b an emission coefficient determination circuit 402c, and a storage circuit 402d. In some embodiments, the parameter measurement circuit 402a, the contact resistance estimation circuit 402b, the emission coefficient determination circuit 402c and the storage circuit 402d may comprise a plurality of parameter measurement circuits, a plurality of contact resistance estimation circuits and a plurality of emission coefficient determination circuits respectively associated therewith, in order to perform measurements on a plurality of input pins of the DUT 404. In some embodiments, the test circuit 402 is configured to determine an emission coefficient associated with an input pin of the DUT 404. In some embodiments, the input pin) of the DUT 404 may comprise a diode element associated therewith and the emission coefficient n is a variable to account for imperfections in the junctions within a diode element, as explained above with respect to FIG. 1.

In embodiments the parameter measurement circuit 402a, the contact resistance estimation circuit 402b, the emission coefficient determination circuit 402c and the storage circuit 402d are implemented as hardware circuits. In some embodiments the parameter measurement circuit 402a, the contact resistance estimation circuit 402b, the emission coefficient determination circuit 402c and the storage circuit 402d are implemented with a hardware core together with firmware.

In a first example embodiment, the test circuit 402 is configured to determine the emission coefficient associated with an input pin of the DUT, based on implementing the predefined emission coefficient determination method 300 explained above with respect to FIG. 3. In such embodiments, the parameter measurement circuit 402a is configured to perform a plurality of voltage and current measurements (e.g., act 304 in FIG. 3. In some embodiments, the parameter measurement circuit 402a is configured to perform the plurality of voltage and current measurements based on forcing a plurality of currents to the input pin of the DUT 404 and measuring corresponding voltages at the input pin of the DUT 404. However, in other embodiments, the parameter measurement circuit 402a may be configured to perform the plurality of voltage and current measurements based on forcing a plurality of voltages at the input pin of the DUT 404 and measuring corresponding currents at the input pin of the DUT 404.

Referring back to FIG. 4, in some embodiments, the test circuit 402 may be further configured to determine the emission coefficient using emission coefficient determination circuit 402b and equation (2) or (3) above. Further, the contact resistance estimation circuit 402c is configured to implement the equation (1) based on the determined contact resistance parameter set, and a value of the emission coefficient n, and hence to determine the contact resistance. In such embodiments, the contact resistance estimation circuit 402c may be configured to use a select voltage and current measurement determined at the parameter measurement circuit 402 during the emission coefficient determination process to determine the contact resistance. Alternately, in other embodiments, the contact resistance estimation circuit 402c may use a new set of parameters measured by the parameter measurement circuit 402a.

In some embodiments, contact resistance is determined at the contact resistance estimation circuit 402c based on implementing the method 300 as explained above.

Note that in some embodiments the contact resistance estimation circuit 402c is connected indirectly to the output of the parameter measurement circuit 402a through emission coefficient determination circuit 402b. In some embodiments, the contact resistance estimation circuit is connected additionally directly to the parameter measurement circuit as illustrated by optional dotted line connection 410 in FIG. 4.

In some embodiments the determined contact resistance is then stored in storage circuit 402d. In some embodiments, both the determined emission coefficient and the determined contact resistance are stored.

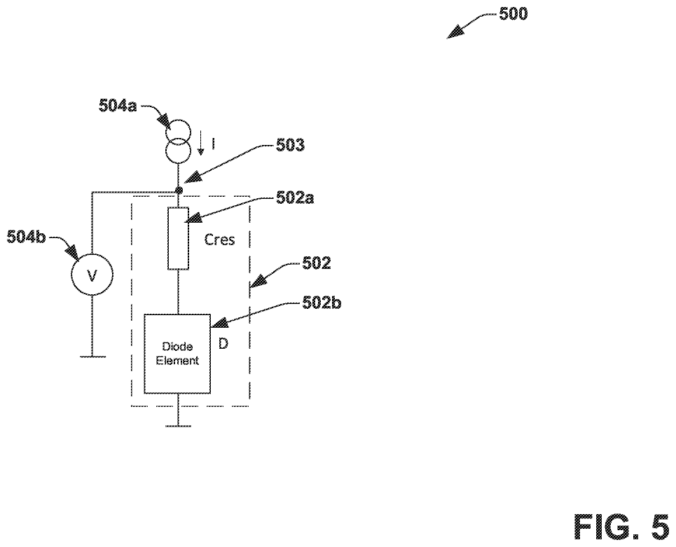

FIG. 5 illustrates one possible simplified test setup 500 configured to measure a contact resistance associated with a DUT, according to one embodiment of the disclosure. The test setup 500 comprises a device under test 502, a current source 504a configured to force current I into an input pin 503 of the DUT 500 and a voltage measurement circuit 504b configured to measure a voltage at the input pin 503 of the DUT 500. In some embodiments, the current source 504a and the voltage measurement circuit 504b may be part of the test circuit 102 in FIG. 1 and the DUT 502 may be included within the DUT 104 in FIG. 1. In this example embodiment, the test setup is shown to include a current source 504a and a voltage measurement circuit 504b, in order to perform the voltage and current measurements. However, in other embodiments, the test setup may include a voltage source and a current measurement circuit, in order to perform the voltage and current measurements. In some embodiments, the contact resistance value may be determined based on information of the voltage measured V_{measured} \ at the voltage measurement circuit 502b and the induced current I. In some embodiments, a voltage measured V_{measured} \ at the input pin 503 of the DUT 500 comprises a voltage drop due to a contact resistance Cres 502a and the voltage across the diode element D 502b.

While the methods are illustrated and described above as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

While the apparatus has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

In particular regard to the various functions performed by the above described components (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature may have been disclosed with respect to only one of several implementations, such feature may be combined with one or more other features of the other implementations as may be desired and advantageous for any given or particular application.

While the invention has been illustrated, and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

Examples can include subject matter such as a method, means for performing acts or blocks of the method, at least one machine-readable medium including instructions that, when performed by a machine cause the machine to perform acts of the method or of an apparatus or system for concurrent communication using multiple communication technologies according to embodiments and examples described herein.

Various illustrative logics, logical blocks, modules, and circuits described in connection with aspects disclosed herein can be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform functions described herein. A general-purpose processor can be a microprocessor, but, in the alternative, processor can be any conventional processor, controller, microcontroller, or state machine.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

In particular regard to the various functions performed by the above described components (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature may have been disclosed with respect to only one of several implementations, such feature may be combined with one or more other features of the other implementations as may be desired and advantageous for any given or particular application.

What is claimed is:

1. A method comprising:
(a) performing voltage and current measurements associated with a pin of a device under test (DUT) using a parameter measurement circuit, obtaining at least three voltage-current measurement pairs;
(b) determining an emission coefficient from the voltage-current measurement pairs;
(c) calculating a contact resistance from the emission coefficient and the voltage-current measurement pairs; and
(d) storing the calculated contact resistance and/or emission coefficient in a memory circuit for subsequent access in testing or validating the DUT.

2. The method of claim 1, wherein currents of the voltage-current measurement pairs comprise a low current I_{low}, a mid current I_{mid} and a high current I_{high}, and the respective measured voltages comprise a low voltage V_{low}, a mid voltage V_{mid} and a high Voltage V_{high}.

3. The method of claim 2 wherein calculating the emission coefficient solves an equation as foIlows
$$\frac{( Vhigh - Vlow ) - ( η . V T . ln ( \frac{Ihigh}{Ilow} ) )}{Ihigh - Ilow} = \frac{( Vhigh - Vlow ) - ( η . V T . ln ( \frac{Ihigh}{Imid} ) )}{Ihigh - Imid}$$
for n.

4. The method of claim 2 wherein the low current I_{low}, the mid current I_{mid} and the high current I_{high} are in a ratio 1:2:4 and wherein calculating the emission coefficient uses an equation as foIlows:
$$η = \frac{ABS ( 2 * ( Vhigh - Vlow ) ) - ABS ( 3 * ( Vhigh - Vmid ) )}{V T * ln ( 2 )}$$
where η is the emission coefficient, ABS( ) represents an absolute value function, VT is a voltage threshold of the device and In a natural logarithm function.

5. The method of claim 2, wherein calculating the contact resistance comprises using at least one of the foIlowing equations
$$CRES 1 = \frac{( Vhigh - Vlow ) - ( η . V T . ln ( \frac{Ihigh}{Ilow} ) )}{Ihigh - Ilow} CRES 2 = \frac{( Vhigh - Vlow ) - ( η . V T . ln ( \frac{Ihigh}{Imid} ) )}{Ihigh - Imid}$$
where CRES1 and CRES2 represent the contact resistance.

6. The method of claim 1, further comprising testing a device, wherein a resistance of a physical connection between the device and a test circuit is a basis for the calculated contact resistance.

7. The method of claim 1, further comprising performing further voltage and current measurements associated with at least one other pin of a device under test (DUT) using a parameter measurement circuit, obtaining at least two further voltage-current measurement pairs; and
calculating a further contact resistance using the further voltage-current measurement pairs.

8. A computer program product recorded on a data carrier, adapted to be input in a test system to cause the test system:
(a) to perform voltage and current measurements associated with a pin of a device under test (DUT) using a parameter measurement circuit, obtaining at least three voltage-current measurement pairs;
(b) to determine an emission coefficient from the voltage-current measurement pairs;
(c) to determine a contact resistance from the emission coefficient and the voltage-current measurement pairs; and
(d) to store the determined contact resistance and emission coefficient in a memory circuit for subsequent access in testing or validating the DUT.

9. The computer program product of claim 8, wherein computer program product is arranged to cause the test system to supply currents of the voltage-current measurement pairs comprising a low current I_{low}, a mid current I_{mid} and a high current I_{high}, and with the respective being a low voltage V_{low}, a mid voltage V_{mid} and a high Voltage V_{high}.

10. The computer program product of claim 9 wherein arranged to determine the emission coefficient using the foIlowing equation
$$\frac{( Vhigh - Vlow ) - ( η . V T . ln ( \frac{Ihigh}{Ilow} ) )}{Ihigh - Ilow} = \frac{( Vhigh - Vlow ) - ( η . V T . ln ( \frac{Ihigh}{Imid} ) )}{Ihigh - Imid}$$
for η.

11. The computer program product of claim 9 wherein the computer program product is arranged to cause the test system to supply the low current I_{low}, the mid current I_{mid} and the high current I_{high} in a ratio 1:2:4 and wherein calculating the emission coefficient uses the following equation
$$η = \frac{ABS ( 2 * ( Vhigh - Vlow ) ) - ABS ( 3 * ( Vhigh - Vmid ) )}{V T * ln ( 2 )}$$
where η is the emission coefficient, where ABS( ) represents an absolute value function, VT is a voltage threshold of the device and In is a natural logarithm function.

12. The computer program product of claim 9, arranged to calculate the contact resistance using at least one of the foIlowing equations:
$$CRES 1 = \frac{( Vhigh - Vlow ) - ( η . V T . ln ( \frac{Ihigh}{Ilow} ) )}{Ihigh - Ilow} CRES 2 = \frac{( Vhigh - Vlow ) - ( η . V T . ln ( \frac{Ihigh}{Imid} ) )}{Ihigh - Imid}$$
where CRES1 and CRES2 represent the contact resistance.

13. A test circuit configured to determine an emission coefficient of a device under test (DUT), comprising:
(a) a parameter measurement circuit connected to a test connection for associating with a pin of a device under test (DUT);
(b) an emission coefficient determination circuit connected to an output of the parameter measurement circuit; and
(c) a contact resistance determination circuit connected to the output of the parameter measurement circuit and an output of the emission coefficient determination circuit.

14. A test circuit according to claim 13 further comprising a storage circuit for storing the determined contact resistance and/or emission coefficient.
